(19) United States
(12) Patent Application Publication
(10) Pub. No.: US 2025/0062714 A1
(43) Pub. Date: Feb. 20, 2025

(54) PHOTOVOLTAIC MODULE AND METHOD FOR PRODUCING A PHOTOVOLTAIC MODULE

(71) Applicant: TubeSolar AG, Bayreuth (DE)

(72) Inventor: Johann MAYER, Bayreuth (DE)

(73) Assignee: TubeSolar AG, Bayreuth (DE)

(21) Appl. No.: 18/719,370

(22) PCT Filed: Nov. 28, 2022
(86) PCT No.: PCT/EP2022/083537

§ 371 Date: Jun. 13, 2024

(30) Foreign Application Priority Data
Dec. 15, 2021 (DE) 10 2021 133 195.1

(51) Int. Cl. H02S 30/00; H02S 40/30

(52) U.S. Cl. CPC H02S 30/00; H02S 40/30

(57) ABSTRACT

A photovoltaic module (12) ensures a highly durable, integrally bonded sealing of the interior (18) of the tube (16). The photo-voltaic module (12) is easy and cost-effective to produce and the efficiency of the photovoltaic module (12) in relation to the effective area for energy conversion is not compromised or is only negligibly compromised. The photovoltaic module (12) is very low-maintenance and has a long service life. Furthermore, the photovoltaic module (12) can be arranged with respect to a plurality of photovoltaic modules (12) arranged in parallel and can form a solar module formed for example from 20 photovoltaic modules (12).

### CROSS-REFERENCE TO RELATED APPLICATION

This application is a national stage application, filed under 35 U.S.C. § 371, of International Patent Application PCT/EP2022/0835307, filed on Nov. 28, 2022, which claims the benefit of German Patent Application DE 10 2021 133 195.1, filed on Dec. 15, 2021.

### TECHNICAL FIELD

The present disclosure relates to a photovoltaic module, and to a method for producing a photovoltaic module.

### BACKGROUND

Photovoltaic modules are generally known, for example from DE 10 2014 225 631 A1 and WO 2009/038794 A1. In this case, a plurality of photovoltaic modules exist, which, arranged in parallel with one another, form large solar modules.

Photovoltaic modules of this kind can be used in a versatile manner, but in particular for energy harvesting on agricultural land, since agriculture can still operate under the photovoltaic modules.

In the case of these photovoltaic modules, a solar cell arrangement is located in a tube, which usually consists of glass or plastics material. Plastics caps are placed on these tubes and are usually also adhesively bonded thereto, as a result of which sealing of the tube interiors takes place. Energy consumption from the solar cell arrangement also takes place simultaneously using said plastics caps.

A disadvantage of this embodiment is that the sealing is not highly durable.

### SUMMARY

An object of the present disclosure is that of proposing a photovoltaic module in which highly durable sealing of the interior of the tube is ensured. In particular, the sealing is intended to be easy and cost-effective to produce and the efficiency in relation to the effective area for energy conversion should not be compromised or be only negligibly compromised. The photovoltaic module should preferably be low-maintenance and have a long service life.

This object is achieved by the photovoltaic module as disclosed and claimed, and by the method as disclosed and claimed.

The inventors have found that this object can be achieved in a surprising manner and particularly easily if the coefficient of thermal expansion of the tube and the closure element are adjusted to one another in such a way that, in the course of the normal operating temperatures of such photovoltaic modules (−40° to 105° C.) no gaps can form between the tube and the closure element. As a result, the penetration of damp air or oxygen into the interior of the tube can be prevented, as a result of which both the electrical contacts and lines, and the solar cell arrangement itself, are protected. In an extreme case, otherwise a short circuit could occur, which destroys the entire photovoltaic module, or the electrical contact points (photovoltaically active layer to the electrical wire) can oxidize and become high-impedance.

The photovoltaic module according to the invention comprises:
a tube that surrounds an interior and is translucent at least in regions, comprising a longitudinal axis and an inner surface facing the interior,
a photovoltaic component comprising a solar cell arrangement, wherein the photovoltaic component is arranged in the interior and the solar cell arrangement covers the inner surface at least in part, and
a closure element which closes the tube along the longitudinal axis in a form-fitting and/or integrally bonded manner, and is characterized in that the closure element consists of a material of which the coefficient of thermal expansion differs from that of the tube only by at most 10%. The difference is preferably only at most 5%.

In an advantageous development it is provided that the tube comprises glass and/or the closure element comprises glass, wherein preferably both the tube and the closure element consist of glass (e.g. of soda lime). As a result, the photovoltaic module is particularly durable, because glass, in contrast to plastics material, cannot embrittle and become cracked, as a result of which an even better sealing of the interior is ensured. Furthermore, glass can be interconnected particularly well in an integrally bonded manner.

In an advantageous development it is provided that the closure element is designed to be soldered, welded, adhesively bonded, fused or vulcanised to the tube, wherein for the event that the closure between the closure element and the tube is produced by an additional material providing the integral bond, the additional material consists of a substance of which the coefficient of thermal expansion differs from that of the tube and of the closure element only by at most 10%. The difference is preferably only at most 5%. A particularly good and highly durable sealing of the interior is brought about thereby.

In an advantageous development it is provided that welding or melting is performed at temperatures in the range of 750° C. to 1100° C., preferably in the range of 900° C. to 1050° C., in particular at 1000° C. A particularly reliable connection is produced as a result.

In an advantageous development it is provided that a closure element exists in each case on both sides of the tube. As a result, the photovoltaic module can be produced particularly easily and cost-effectively.

In an advantageous development it is provided that the closure element has an axially curved shape (e.g. convex or concave), at least in regions, in a cross-section along the longitudinal axis, wherein the curved shape is preferably formed continuously in the peripheral direction, wherein the curved shape is designed in particular as a fold. As a result, the closure element can have e.g. a conical shape, cylindrical shape, flattened dome shape or ball shape. By means of these measures, the connection between the closure element and the tube is reinforced, as a result of which the photovoltaic module has a higher loading capacity.

In an advantageous development it is provided that the photovoltaic module is filled with a protective gas, wherein the protective gas preferably comprises at least one of the substances from the group: dried air, nitrogen, inert gas, preferably argon or helium, hydrogen, SF6, and gas mixtures of said gases. As a result, there is an even greater protection against penetration of moisture of oxygen.

In an advantageous development it is provided that the solar cell arrangement is at a distance of at least 1 mm, preferably at least 3 mm, preferably at least 4 mm, and in particular at least 5 mm from the closure element, with respect to the longitudinal axis. As a result, damage to the solar cell arrangement when establishing the form-fitting or integrally bonded connection between the tube and the closure element is prevented.

In an advantageous development it is provided that the solar cell arrangement is at a distance of at most 100 mm, preferably at most 40 mm, preferably at most 30 mm, and in particular at most 20 mm from the closure element, with respect to the longitudinal axis. As a result, the photovoltaically usable surface of the photovoltaic module can be prevented from thermal damage by the form-fitting connection (e.g. glass fusing) between the glass tube and glass closure element.

In an advantageous development it is provided that there is at least one contact element which is guided through the closure element or between the closure element and tube, wherein the contact element is connected to the closure element and/or the tube in an integrally bonded manner, wherein the contact element preferably consists of a material of which the coefficient of thermal expansion differs from that of the closure element and/or that of the tube only by at most 10%. The difference is preferably only at most 5%. As a result, no leaks can occur, even in the case of contact leadthroughs.

In an advantageous development it is provided, for the event that the closure between the contact element and the closure element or between the contact element and the tube is produced by an additional material providing the integral bond, the additional material consists of a substance of which the coefficient of thermal expansion differs from that of the tube and/or of the closure element only by at most 10%. The difference is preferably only at most 5%. As a result, the closure is sealed securely and durably against penetration of moisture or oxygen.

In an advantageous development it is provided that a contact element comprises nickel. Nickel or nickel alloys have a coefficient of thermal expansion that is very well adapted to glass.

In an advantageous development it is provided that a contact element exists in which a central contact region exists for melting into the closure element or for melting in between the tube and closure element, having a coefficient of thermal expansion that is adapted to the material of the closure element and/or the tube, and contact regions comprising different materials are located on both sides of said central contact region. For example, the contact region leading to the outside can be formed of copper-plated steel, in order to ensure good welding properties, and the contact region leading to the solar cell arrangement can comprise a metal or metal alloy, which has good contact compatibility with the solar cell arrangement, in order to prevent electrocorrosion.

In an advantageous development it is provided that the melting in is performed at temperatures in the range of 750° C. to 1100° C., preferably in the range of 900° C. to 1050° C., in particular at 1000° C. A particularly reliable connection is produced as a result.

In an advantageous development it is provided that the contact element is designed as a wire and has a thickness in the range of 0.1 mm to 3 mm, preferably in the range of 0.1 mm to 2 mm, in particular in the range of 0.2 mm to 1 mm. As a result, a reliable and low-resistance current guidance of the contact element edging can be achieved.

Alternatively, the contact element can also be designed having any geometric shape, for example as a sheet having a cross-sectional area of 0.1 mm² to 3 mm².

In an advantageous development, it is provided that the inner surface is designed to be curved at least in regions, preferably in the shape of a circular arc, at least in regions, in a cross-section to the longitudinal axis. As a result, the photovoltaic module is particularly efficient, since for example in the case of a north/south orientation of the photovoltaic module almost perpendicular incident radiation of the sunlight is made possible.

In an advantageous development, it is provided that the tube is designed to be curved at least in regions, preferably in the shape of a circular arc, at least in regions, in a cross-section to the longitudinal axis. As a result, the photovoltaic module is particularly efficient.

In an advantageous development it is provided that the photovoltaic module is designed to be mechanically flexible, comprising a carrier foil on which the solar cell arrangement is arranged. As a result, the photovoltaic module can be produced particularly easily, as is described for example in DE 10 2014 225 631 A1.

In an advantageous development it is provided that the solar cell arrangement follows the course of the inner surface, at least in regions. As a result, the photovoltaic module is particularly efficient.

A method for producing a photovoltaic module, comprises:
a tube that surrounds an interior and is translucent at least in regions, comprising a longitudinal axis and an inner surface facing the interior,
a photovoltaic component comprising a solar cell arrangement, wherein the photovoltaic component is arranged in the interior and the solar cell arrangement covers the inner surface at least in part, and
a closure element which closes the tube along the longitudinal axis in an integrally bonded manner, wherein the method is characterized in that a closure element is used which consists of a material of which the coefficient of thermal expansion differs from that of the tube only by at most 10%. The difference is preferably only at most 5%.

In an advantageous development it is provided that the photovoltaic module according to the invention is produced.

The photovoltaic component can essentially be one that is designed or produced as desired. For example, it can be a component of a type that is based on CIGS (containing copper, indium, gallium and selenium) or perovskite. It can, however, for example also be what is known as a tandem cell made of CIGS and perovskite, or of perovskite and thin SI layers, as well as amorphous or μ-crystalline SI layers.

In an advantageous development it is provided that a closure element is used which comprises an aperture, preferably in the form of a small tube, via which the tube is filled with the protective gas, wherein the tube is closed after the integrally bonded connection has been established, is preferably closed in an integrally bonded manner, wherein the closure of the small tube is preferably created by melting together the small tube. The small tube can have an inside diameter in the range of 1 mm to 5 mm, preferably in the range of 2 mm to 4 mm. As a result, the tube can be easily filled with a protective gas, and the subsequent sealing is possible in a durable manner.

The features and further advantages of the present invention will become clear in the following, on the basis of the description of a preferred embodiment, in conjunction with the figures.

### BRIEF DESCRIPTION OF THE DRAWINGS

FIG. 1 shows a solar module comprising photovoltaic modules according to the invention,

FIG. 2 is a detailed side view of the photovoltaic module according to the invention, according to a first preferred embodiment, before closure,

FIG. 3 is a detailed side view of the photovoltaic module according to the invention, according to FIG. 2, after closure,

FIG. 4 is a plan view from the side of the photovoltaic module according to the invention, according to FIG. 2, after closure,

FIG. 5 is a sectional view through the closure element of the photovoltaic module according to the invention according to FIG. 2,

FIG. 6 is a detailed side view of the photovoltaic module according to the invention, according to a second preferred embodiment, before closure,

FIG. 7 is a detailed side view of the photovoltaic module according to the invention, according to a third preferred embodiment, before closure, and

FIG. 8 is a side view of the closure element according to the invention, according to a fourth preferred embodiment.

### DETAILED DESCRIPTION

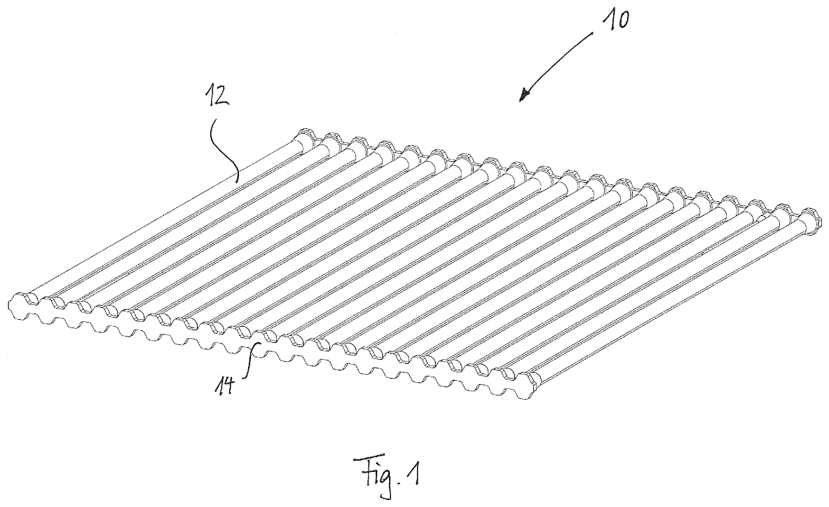

FIG. 1 shows the solar module 10 according to the invention, which consists of a plurality of photovoltaic modules 12 according to the invention which are arranged in parallel in a surface and which each comprise an edging 14 on both sides.

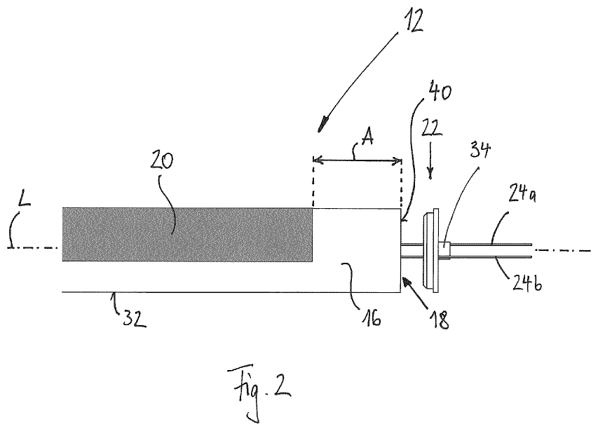

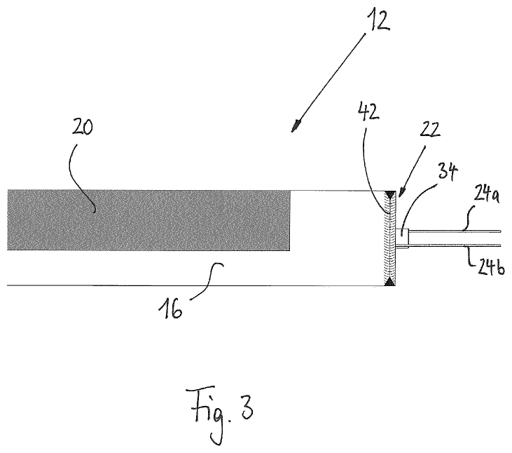

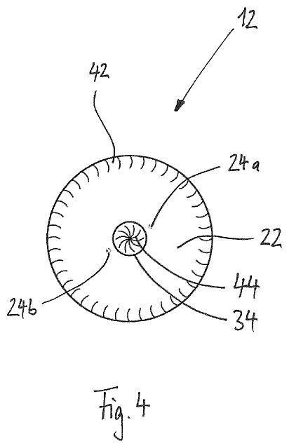

FIGS. 2 to 5 are different detailed views of the photovoltaic module 12 according to the invention, according to a first preferred embodiment.

It can be seen that the photovoltaic module 12 comprises a tube 16 made of glass or plastics material and comprising an interior 18, wherein a solar cell arrangement 20 is arranged in the interior 18. More precisely, the glass tube 16 has a hollow-cylindrical shape having a circular cross-section in the longitudinal direction L. In this case, the solar cell arrangement 20 follows the contour course of the inner surface of the glass tube 16 facing the interior 18, i.e. rests closely on the glass tube 16, and covers said inner surface at least in part.

A form-fitting connection between the inner surface of the glass tube 16 and the incident light side of the solar cell arrangement 20 a melt foil (not shown), e.g. polyolefins, EVA, PVB, silicone, connects the two surfaces via a thermal process (at typically 140° C.).

Since the tube 16 consists of glass, it is translucent, such that the solar cell arrangement 20 can convert incident light into power. The solar cell arrangement 20 is for example one that is of a type that is based on CIGS (containing copper, indium, gallium and selenium) or perovskite. It can, however, for example also be what is known as a tandem cell made of CIGS and perovskite, or of perovskite and thin SI layers, as well as amorphous or u-crystalline SI layers.

Furthermore, a closure element 22 exists, which closes the tube 16 in a form-fitting and/or integrally bonded manner along the longitudinal axis L. Said closure element 22 also consists of glass, wherein additional contact wires 24a, 24b for electrically contacting the solar cell arrangement 20 exist. The contact wires consist of a nickel-containing metal alloy, for example NiFe47Cr6, which has a very similar coefficient of thermal expansion to the glass of the tube 16 and of the closure element 22. The coefficients of thermal expansion of the tube 16 and closure element 22 therefore do not differ, and those of the closure element 22 and contact wires 24a, 24b differ only by less than approximately 10%.

In the context of this preferred embodiment, the contact elements are formed, as contact wires 24a, 24b, homogeneously of one material. It could alternatively also be provided, however, that the contact element comprises a central contact region for melting into the closure element or for melting in between the tube and closure element, having a coefficient of thermal expansion that is adapted to the material of the closure element and/or the tube, and contact regions comprising different materials (not shown) extend on both sides of said central contact region.

The closure element 22 is in the form of a plug, having a central middle part 26, the outside diameter of which is dimensioned such that it can be inserted into the tube 16 in a fitting manner. In the front region, the closure element 22 has a chamfer 28, for facilitated introduction of the closure element 22 into the tube 16. A collar 30 exists in the rear region, which collar is of such a height h relative to the middle part 26 that the closure element 22 terminates radially with the outer surface 32 of the tube 16.

The closure element 22 is designed to be solid over its body, apart from a small tube 34 made of glass, which forms a central aperture 36 in the closure element 22.

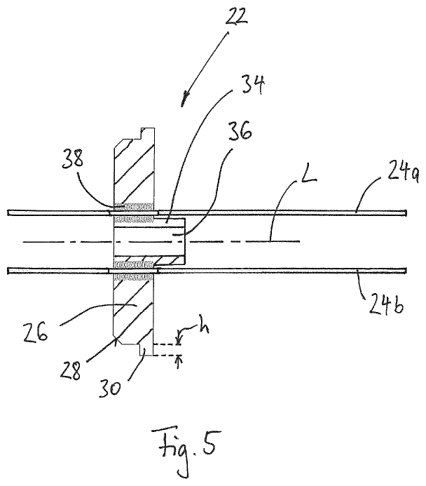

Furthermore, it can be seen that the two contact wires 24a, 24b are guided through the closure element 22, in addition to the small tube 34, more precisely are melted in 38 (cf. FIG. 5).

The method for producing the photovoltaic element 12 now takes place as follows:

After production of the tube 16 with the solar cell arrangement 20, the closure element 22 is placed centrally on the side opening 40 of the tube 16 by means of the chamfers 28, until the collar 30 is resting closely on the tube 16.

Subsequently, the glass of the tube 16 and of the collar 30 is fused simultaneously with the aid of a laser beam (for example Nd-YAG laser having a wavelength λ=1.064 nm) or with the aid of a gas flame or a plasma burner (not shown) (glass has a melting temperature of approximately 1000° C.), and the fused glass regions are joined together by gently pressing the tube together, with respect to the closure element, in the direction of the longitudinal axis L, as a result of which a permanent and absolutely fluid-tight (i.e. gas-tight and/or liquid-tight) form-fitting and integrally bonded connection (seam) 42 results between the tube 16 and closure element 22.

Since the solar cell arrangement 20 is at a distance A from the seam 42 in the range of from approximately 5 mm to approximately 20 mm, thermal damage to the solar cell arrangement 20 by the melting process is reliably prevented, since heat transport through glass is relatively slight. In this way, the solar cell arrangement 20 is for example not heated above 150° C. (depending on the semiconductor type, e.g. CIGS or perovskite, or tandem cells consisting of both semiconductors, or of perovskite and thin SI layers such as amorphous-or μ-crystalline SI layers), which is non-critical.

Since two identical materials of the tube 16 and closure element 22 exist at the seam 42, and therefore identical coefficients of thermal expansion are present, no gaps or cracks can form at the seam 42 at typical operating temperatures of −40° C. to 105° C.

In the case of the contact wires 24a, 24b melted into the glass of the closure element 22, too, very similar coefficients of thermal expansion are present, such that no cracks or gaps can occur at this point either. As a result, the photovoltaic module 12 is absolutely fluid-tight.

Therefore, the interior 18 can be filled with a protective gas, for further protection against penetrating moisture or oxygen. For this purpose, after cooling of the seam 42, the interior 18 is filled with the protective gas (e.g. nitrogen or an inert gas such as helium) via the small tube 34, such that a pressure difference from ambient pressure of e.g. −300 mbar to +300 mbar is established.

Subsequently, the small glass tube 34, which has a typical inside diameter of 2 mm to 4 mm, is fused and joined 44 thermally using a gas flame, a plasma burner, or a laser beam (not shown), in order to close it in a fluid-tight manner.

As a result, the protective gas is reliably captured in the interior 18 of the photovoltaic element 12. In this case, the tube 16 comprising the solar cell arrangement 20 located therein is hermetically closed by the closure element 22 that is applied in a form-fitting and integrally bonded manner, as a result of which harmful environmental influences cannot penetrate into the tube 16 and there can be no permanent damage to the solar cell arrangement.

Even if in each case only one side of the photovoltaic module 12 is shown in FIGS. 2 to 4, a corresponding closure element (not shown), which has also been melted onto the tube 16, also exists on the other side Said other closure element can be formed either with or without a small tube or contact wires. For example, the filling with protective gas could take place more quickly via said further small tube.

Instead of a continuous contact wire 24a, 24b, a correspondingly combined contact wire (not shown) could also be used, in which a central wire region exists for melting into the closure element, having a coefficient of thermal expansion that is adapted to glass, and other wire regions are located on both sides of said central wire region, wherein for example the wire region leading to the outside can be a copper-plated steel wire, in order to ensure good welding properties, and the wire region leading to the solar cell arrangement comprises a metal or metal alloy, which has good contact compatibility with the solar cell arrangement, in order to prevent electrocorrosion.

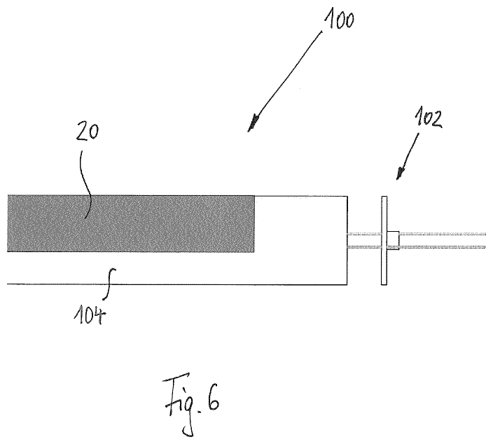

FIG. 6 shows the photovoltaic module 100 according to the invention, according to a second preferred embodiment, before closure.

It can be seen that here the closure element 102 of the tube 104 is not plug-shaped, but rather designed purely as a cover. As a result, the photovoltaic module 100 can be designed to be lighter in weight. Moreover, less material has to be fused during melting, between the closure element 102 and tube 104, such that the photovoltaic module 100 can be produced with less energy consumption.

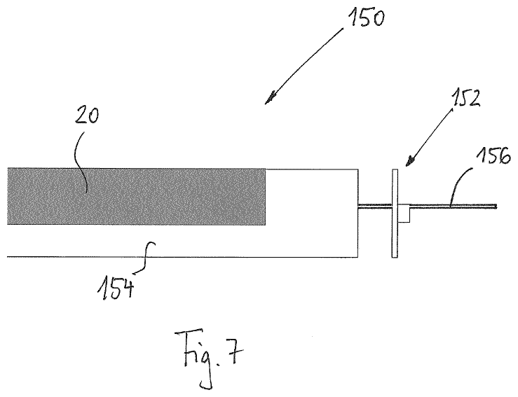

FIG. 7 shows the photovoltaic module 150 according to the invention, according to a third preferred embodiment, before closure.

It can be seen that here the closure element 152 of the tube 154 comprises just one contact wire 156. The other contact wire is guided through the other closure element at the opposite end of the tube 154 (neither shown).

Instead of the two contact wires 24a, 24b shown in the case of the closure element 22, and the one contact wire 156 shown in the case of the closure element 150, more than two, for example 3, 4, 5 or more, contact wires can also be guided through a closure element.

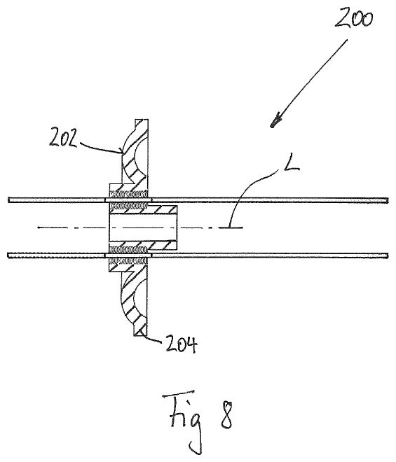

FIG. 8 is a cross-sectional view of a further closure element 200 according to a fourth preferred embodiment of the photovoltaic module according to the invention (not shown).

It can be seen that, here, the closure element 200 has an axially curved shape, at least in regions, in a cross-section along the longitudinal axis L, wherein the curved shape is formed continuously in the peripheral direction. More precisely, a fold 202 exists here, which faces inwards towards the tube of the photovoltaic module (neither shown). As a result, the closure element 200 and thus also the closure between the tube and the closure element 200, and the entire photovoltaic module, are designed to be particularly stable.

Furthermore, a collar 204 also exists again here.

It has become clear from the above description that the present invention provides a photovoltaic module 12, 100, 150, 200, in which highly durable sealing of the interior 18 of the tube 16 is ensured. In this case, the photovoltaic module 12, 100, 150, 200 is easy and cost-effective to produce and the efficiency of the photovoltaic module 12, 100, 150, 200 in relation to the effective area for energy conversion is not compromised or is only negligibly compromised. In this case, the photovoltaic module 12, 100, 150, 200 according to the invention is very low-maintenance and has a long service life.

All the features set out in the general description of the invention, the description of the embodiments, the following claims, and in the drawings, may be essential to the invention both individually and in any desired combination with one another. These features or combinations of features can in each case establish an independent invention, the right to claim which is explicitly reserved. In this case, individual features from the description of an embodiment do not necessarily have to be combined with one or more or all of the features specified in the description of this embodiment; in this respect, every sub-combination is explicitly also disclosed. Furthermore, features, relating to subject matter, of a device can also be used, reworded, as method features, and method features can be used, reworded, as features, related to subject matter, of a device. Such rewording is therefore automatically also disclosed.

### LIST OF REFERENCE SIGNS

10 solar module according to the invention
12 photovoltaic modules according to the invention, according to a first preferred embodiment
14 edging of the photovoltaic modules 12 in the solar module 10
16 tube
18 interior
20 solar cell arrangement
22 closure element
24a, 24b contact wires
26 central middle part of the closure element 22
28 chamfer
30 collar
32 outer surface of the tube 16
34 small tube
36 central aperture
38 melting in of the contact wires 24a, 24b into the closure element 22
40 side opening of the tube 16
42 fluid-tight form-fitting and integrally bonded connection between the tube 16 and the closure element 22, seam
44 fluid-tight fusion of the small tube 34
100 photovoltaic module according to the invention, according to a second preferred embodiment
102 closure element
104 tube
150 photovoltaic module according to the invention, according to a third preferred embodiment
152 closure element
154 tube
156 contact wire
200 closure element according to the invention, according to a fourth preferred embodiment of the photovoltaic module
202 fold
204 collar
A distance of the solar cell arrangement 20 from the seam 42
h height of the collar 30 relative to the middle part 26
L longitudinal direction

1.-10. (canceled)

11. A photovoltaic module (12; 100; 150; 200), comprising:
a tube (16; 104; 154) that surrounds an interior (18) and is translucent at least in regions, the tube having a longitudinal axis (L) and an inner surface facing the interior (18);
a photovoltaic component comprising a solar cell arrangement (20), the photovoltaic component being arranged in the interior (18) and the solar cell arrangement (20) covering the inner surface at least in part; and
a closure element (22; 102; 152; 200), which closes the tube in a form-fitting and/or integrally bonded manner along the longitudinal axis,
wherein the closure element (22; 102; 152; 200) consists of a material having a coefficient of thermal expansion that differs from that of the tube by at most 10%.

12. The photovoltaic module (12; 100; 150; 200) according to claim 11,
wherein both the tube (16; 104; 154) and the closure element (22; 102; 152; 200) consist of glass.

13. The photovoltaic module (12; 100; 150; 200) according to claim 11,
wherein the closure element (22; 102; 152; 200) is designed to be soldered, welded, adhesively bonded, fused (42) or vulcanized to the tube (16; 104; 154) by an integral bond,
wherein any additional material providing the integral bond consists of a substance having a coefficient of thermal expansion that differs from that of the tube and of the closure element by at most 10%.

14. The photovoltaic module (12; 100; 150; 200) according to claim 11,
wherein the closure element (22; 102; 152; 200) includes at least one closure element (22; 102; 152; 200) each on both sides of the tube (16; 104; 154).

15. The photovoltaic module (12; 100; 150; 200) according to claim 11,
wherein the closure element (200) has an axially curved shape, at least in regions, in a cross-section along the longitudinal axis (L), and
wherein the axially curved shape is formed continuously in a peripheral direction.

16. The photovoltaic module (12; 100; 150; 200) according to claim 11,
wherein the closure element (200) has an axially curved shape, at least in regions, in a cross-section along the longitudinal axis (L), and
wherein the axially curved shape is designed as a fold (202).

17. The photovoltaic module (12; 100; 150; 200) according to claim 11,
wherein the photovoltaic module (12; 100; 150; 200) is filled with a protective gas,
wherein the protective gas comprises at least one of the substances selected from the group consisting of: dried air, nitrogen, inert gases, argon, helium, hydrogen, SF6, and gas mixtures thereof.

18. The photovoltaic module (12; 100; 150; 200) according to claim 11,
wherein the solar cell arrangement (20) is at a distance (A) of at least 1 mm from the closure element (22; 102; 152; 200), with respect to the longitudinal axis (L), and/or
wherein the solar cell arrangement (20) is at a distance (A) of at most 100 mm from the closure element (22; 102; 152; 200), with respect to the longitudinal axis (L).

19. The photovoltaic module (12; 100; 150; 200) according to claim 11,
further comprising a contact element (24a, 24b; 156) which is guided through the closure element (22; 102; 152; 200) or between the closure element and tube (16; 104; 154),
wherein the contact element (24a, 24b; 256) is connected to the closure element (22; 102; 152; 200) and/or the tube (16; 104; 154) in a form-fitting and/or integrally bonded manner, and
wherein the contact element (24a, 24b; 156) consists of a material having a coefficient of thermal expansion that differs from that of the closure element (22; 102; 152; 200) and/or that of the tube (16; 104; 154) by at most 10%.

20. The photovoltaic module (12; 100; 150; 200) according to claim 19,
wherein a closure between the contact element and the closure element or between the contact element and the tube is produced by an additional material providing an integral bond, and
wherein the additional material consists of a substance having a coefficient of thermal expansion differs from that of the tube and/or of the closure element by at most 10%.

21. The photovoltaic module (12; 100; 150; 200) according to claim 19,
wherein the contact element (24a, 24b; 156) comprises nickel.

22. The photovoltaic module (12; 100; 150; 200) according to claim 19,
wherein the contact element comprises a central contact region for melting into the closure element or for melting in between the tube and closure element, having a coefficient of thermal expansion that is adapted to the material of the closure element and/or the tube, and contact regions comprising different materials extend on both sides of the central contact region, and
wherein the contact element (24a, 24b; 156) is a wire and having a thickness in a range of 0.1 mm to 3 mm.

23. The photovoltaic module (12; 100; 150; 200) according to claim 11,
wherein the inner surface is curved in shape of a circular arc, at least in regions, in a cross-section to the longitudinal axis.

24. The photovoltaic module (12; 100; 150; 200) according to claim 11,
wherein the tube (16; 104; 154) is curved in shape of a circular arc, at least in regions, in a cross-section to the longitudinal axis.

25. The photovoltaic module (12; 100; 150; 200) according to claim 11,
wherein the photovoltaic module (12; 100; 150; 200) is designed to be mechanically flexible, comprising a carrier foil on which the solar cell arrangement (20) is arranged.

26. The photovoltaic module (12; 100; 150; 200) according to claim 11,
wherein the solar cell arrangement (20) follows a course of the inner surface, at least in regions.

27. A method for producing a photovoltaic module (12; 100; 150; 200), comprising:
providing a tube (16; 104; 154) that surrounds an interior (18) and is translucent at least in regions, the tube having a longitudinal axis (L) and an inner surface facing the interior (18),
providing a photovoltaic component comprising a solar cell arrangement (20) and arranging the photovoltaic component in the interior (18) such that the solar cell arrangement (20) covers the inner surface at least in part; and
closing the tube (16; 104; 154) in a form-fitting and/or integrally bonded manner along the longitudinal axis (L) using a closure element (22; 102; 152; 200) which consists of a material having a coefficient of thermal expansion that differs from that of the tube (16; 104; 154) by at most 10%.

28. The method according to claim 27, further comprising:
filling the tube (16; 104; 154) with a protective gas through an aperture (36) in form of a small tube (34) extending through the closure element (22; 102; 152; 200); and
closing the tube (16; 104; 154) after an integrally bonded connection (42) has been established by melting together the small tube (34).
